(19) United States
(12) Patent Application Publication
(10) Pub. No.: US 2015/0214432 A1
(43) Pub. Date: Jul. 30, 2015

(54) OPTICAL DEVICE AND MANUFACTURING METHOD THEREFOR

(71) Applicant: DISCO CORPORATION, Tokyo (JP)

(72) Inventors: Naotoshi Kirihara, Tokyo (JP); Chikara Aikawa, Tokyo (JP); Yusaku Ito, Tokyo (JP); Taro Arakawa, Tokyo (JP); Yang Tzuchun, Tokyo (JP)

(21) Appl. No.: 14/601,859

(22) Filed: Jan. 21, 2015

(30) Foreign Application Priority Data
Jan. 27, 2014 (JP) 2014-012519

(51) Int. Cl. H01L 33/24; H01L 33/00

(52) U.S. Cl. CPC H01L 33/24; H01L 33/005

(57) ABSTRACT

An optical device including a substrate and a light emitting layer formed on the front surface of the substrate. The back surface of the substrate is formed with a concave portion like a crater. The concave portion is formed by applying a laser beam having an absorption wavelength to an optical device wafer. In the optical device, light emitted from the light emitting layer strikes the inner surface of the concave portion and is next irregularly reflected from the inner surface of the concave portion.

### BACKGROUND OF THE INVENTION

1. Field of the Invention

The present invention relates to an optical device composed of a substrate and a light emitting layer formed on the front surface of the substrate and also to a manufacturing method for the optical device.

1. Description of the Related Art

In a fabrication process for an optical device such as a laser diode (LD) and a light emitting diode (LED), a light emitting layer (epitaxial layer) is formed by epitaxial growth, for example, on the upper surface (front surface) of a crystal growing substrate of sapphire, SiC, or the like, thereby manufacturing an optical device wafer for forming a plurality of optical devices. The light emitting layer formed on the crystal growing substrate of the optical device wafer is partitioned by a plurality of crossing division lines to define a plurality of separate regions where the plural optical devices such as LDs and LEDs are respectively formed. The optical device wafer is divided along these division lines to obtain the individual optical devices as chips.

As a method of dividing the optical device wafer along the division lines, there are known methods as described in Japanese Patent Laid-open Nos. Hei 10-305420 and 2008-006492. The dividing method described in Japanese Patent Laid-open No. Hei 10-305420 includes the steps of applying a pulsed laser beam having an absorption wavelength to the wafer along the division lines to form a laser processed groove along each division line and next applying an external force to the wafer to thereby break the wafer along each division line where the laser processed groove is formed as a division start point.

On the other hand, the dividing method described in Japanese Patent Laid-open No. 2008-006492 is intended to improve the luminance of the optical device and it includes the steps of applying a pulsed laser beam having a transmission wavelength to the wafer along the division lines in the condition where the focal point of the pulsed laser beam is set inside the wafer, thereby forming a modified layer inside the wafer along each division line and next applying an external force to each division line where the modified layer is formed to be reduced in strength, thereby dividing the wafer along each division line.

### SUMMARY OF THE INVENTION

In each of the dividing methods described in Japanese Patent Laid-open Nos. Hei 10-305420 and 2008-006492, the laser beam is directed to the optical device wafer substantially perpendicularly thereto to form the laser processed groove or the modified layer and then divide the optical device wafer along the laser processed groove or the modified layer as a division start point, thereby obtaining the individual optical devices. Each optical device has a rectangular boxlike shape such that each side surface is substantially perpendicular to the light emitting layer formed on the front surface of the substrate. Accordingly, of the light emitted from the light emitting layer of the optical device and reflected on the back surface of the optical device, the proportion of the light striking each side surface at an incident angle greater than the critical angle is large. As a result, the proportion of the light totally reflected on each side surface is large, so that there is a possibility that the light repeating the internal total reflection in the substrate may finally become extinct in the substrate. Accordingly, the light extraction efficiency of the optical device is reduced to cause a reduction in luminance.

It is therefore an object of the present invention to provide an optical device and a manufacturing method therefor which can improve the light extraction efficiency.

In accordance with an aspect of the present invention, there is provided an optical device including a substrate and a light emitting layer formed on the front surface of the substrate, wherein the back surface of the substrate is formed with a concave portion.

With this configuration, the concave portion is formed on the back surface of the substrate. Accordingly, the light striking the inner surface of the concave portion can be irregularly reflected on the inner surface of the concave portion. Further, of the light irregularly reflected on the inner surface of the concave portion and striking each side surface of the substrate, the proportion of the light striking each side surface at an incident angle less than or equal to the critical angle can be increased. As a result, the proportion of the light totally reflected on each side surface and returned to the light emitting layer can be reduced to thereby increase the proportion of the light emerging from each side surface. That is, the light extraction efficiency can be improved.

In accordance with another aspect of the present invention, there is provided a manufacturing method for optical devices each including a substrate and a light emitting layer formed on the front surface of the substrate, wherein the back surface of the substrate is formed with a concave portion, the manufacturing method including an attaching step of attaching a protective tape to the front side of an optical device wafer having a light emitting layer on the front side, the light emitting layer of the optical device wafer being partitioned by a plurality of crossing division lines to define a plurality of separate regions where the optical devices are respectively formed; a division start point forming step of forming a division start point where division is started along each division line of the optical device wafer after performing the attaching step; a dividing step of applying an external force to the optical device wafer along each division line after performing the division start point forming step, thereby dividing the optical device wafer along each division line to obtain the individual optical devices; and a concave portion forming step of applying a laser beam having an absorption wavelength to the optical device wafer before or after performing the dividing step, thereby forming a plurality of concave portions on the back side of the optical device wafer at the positions respectively corresponding to the optical devices. According to this method, the optical device having the concave portion on the back surface can be manufactured without complication of each step and elongation of the time of each step.

Preferably, the concave portion forming step includes an etching step of etching the inner surface of the concave portion formed on the back side of the optical device wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a schematic perspective view of an optical device according to a preferred embodiment of the present invention as viewed from the back side thereof;

FIG. 2 is a schematic sectional view for illustrating a manner of emission of light from the optical device shown in FIG. 1;

FIG. 3 is a schematic sectional view for illustrating a manner of emission of light from a conventional optical device as a comparison;

FIG. 4 is a perspective view of a laser processing apparatus to be used in manufacturing the optical device shown in FIG. 1;

FIG. 5 is a sectional view for illustrating an attaching step;

FIG. 6A is a sectional view for illustrating a division start point forming step;

FIG. 6B is a sectional view for illustrating a concave portion forming step; and

FIG. 6C is a sectional view for illustrating a dividing step.

### DETAILED DESCRIPTION OF THE PREFERRED EMBODIMENT

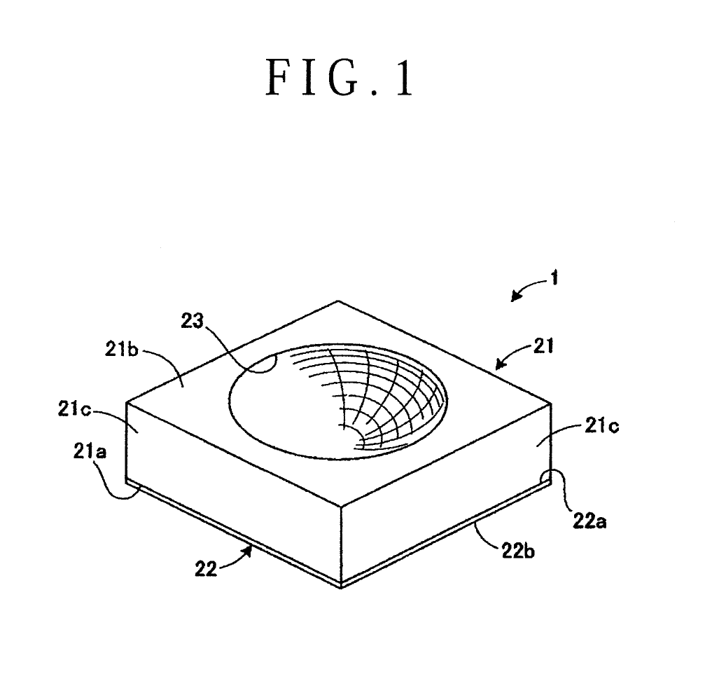

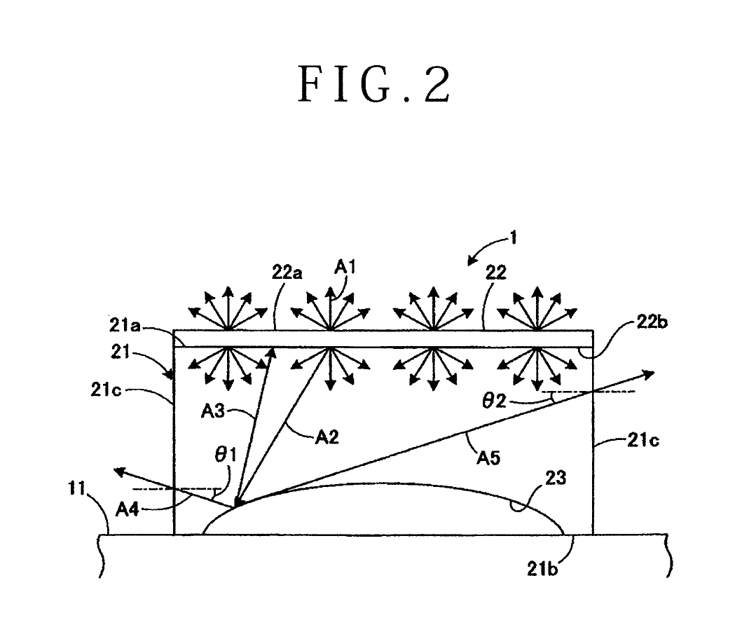

A preferred embodiment of the optical device and the manufacturing method therefor according to the present invention will now be described in detail with reference to the attached drawings. There will first be described a preferred embodiment of the optical device according to the present invention with reference to FIGS. 1 and 2. FIG. 1 is a schematic perspective view of an optical device 1 according to this preferred embodiment as viewed from the back side thereof, and FIG. 2 is a schematic sectional view for illustrating a manner of emission of light from the optical device 1 shown in FIG. 1.

As shown in FIGS. 1 and 2, the optical device 1 is adapted to be mounted on a base 11 (not shown in FIG. 1) by wire bonding or flip chip bonding. The optical device 1 is composed of a substrate 21 and a light emitting layer 22 formed on the front surface 21a of the substrate 21. The substrate 21 is a crystal growing substrate selected from a sapphire substrate (Al₂O₃ substrate), gallium nitride substrate (GaN substrate), silicon carbide substrate (SiC substrate), and gallium oxide substrate (Ga₂O₃ substrate), for example. The substrate 21 is preferably formed of a transparent material.

The light emitting layer 22 is formed by the epitaxial growth of an n-type semiconductor layer (e.g., n-type GaN layer) in which electrons function as majority carrier, a semiconductor layer (e.g., InGaN layer), and a p-type semiconductor layer (e.g., p-type GaN layer) in which holes function as majority carrier. These layers are epitaxially grown in this order on the front surface 21a of the substrate 21. The light emitting layer 22 is formed with two electrodes (not shown) respectively connected to the n-type semiconductor layer and the p-type semiconductor layer. A voltage from an external power source is applied to the two electrodes to thereby emit light from the light emitting layer 22.

Both the front surface 21a and the back surface 21b of the substrate 21 have substantially the same rectangular shape as viewed in plan and they are parallel to each other. The substrate 21 has four side surfaces 21c respectively connecting the four sides of the front surface 21a and the four sides of the back surface 21b. Each side surface 21c is a flat surface perpendicular to both the front surface 21a and the back surface 21b. The back surface 21b of the substrate 21 is formed with a concave portion 23. The concave portion 23 has a curved inner surface like a crater and it is substantially circular as viewed in bottom plan. The inner surface of the concave portion 23 is treated with etching to remove debris inside the concave portion 23, thereby improving the luminance. Wet etching may be adopted as the etching. The proportion of the area where the concave portion 23 is formed to the total area of the back surface 21b is set to 40 to 80%. While the single concave portion 23 is formed on the back surface 21b of the substrate 21 in this preferred embodiment, a plurality of concave portions may be formed on the back surface 21b of the substrate 21.

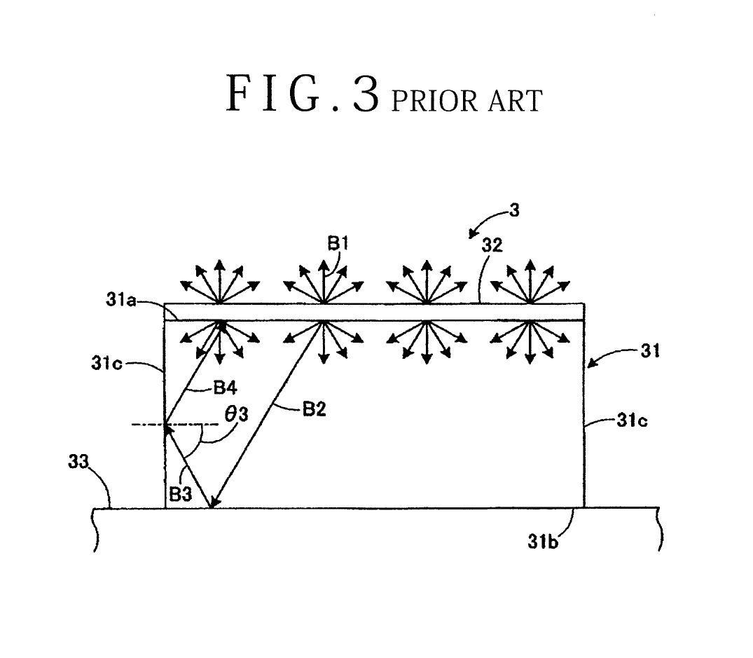

The luminance improving effect by the optical device 1 shown in FIG. 2 will now be described in comparison with a conventional optical device 3 shown in FIG. 3. FIG. 3 is a schematic sectional view for illustrating a manner of emission of light from the optical device 3 as a comparison. The optical device 3 shown in FIG. 3 is similar to the optical device 1 shown in FIG. 2 except the shape of the back surface 21b of the substrate 21. More specifically, the optical device 3 shown in FIG. 3 is composed of a substrate 31 and a light emitting layer 32 formed on the front surface 31a of the substrate 31. Both the front surface 31a and the back surface 31b of the substrate 31 have substantially the same rectangular shape as viewed in plan. The optical device 3 is mounted on a base 33. The substrate 31 has four side surfaces 31c, each of which is a flat surface perpendicular to the front surface 31a and the back surface 31b. The back surface 31b of the substrate 31 is a flat surface parallel to the front surface 31a of the substrate 31.

As shown in FIG. 2, the light generated in the light emitting layer 22 of the optical device 1 according to this preferred embodiment is emitted mainly from the front surface 22a and the back surface 22b. The light emitted from the front surface 22a of the light emitting layer 22 (e.g., optical path Al) is extracted through a lens member (not shown) or the like to the outside. On the other hand, the light emitted from the back surface 22b of the light emitting layer 22 and propagating along an optical path A2 strikes the inner surface of the concave portion 23 and is irregularly reflected on the inner surface of the concave portion 23. The light irregularly reflected on the inner surface of the concave portion 23 propagates along optical paths A3, A4, and A5, for example.

The light propagating along the optical path A3 strikes the light emitting layer 22 and is absorbed by the light emitting layer 22, so that the light cannot be extracted to the outside. The light propagating along the optical path A4 strikes the interface between one of the side surfaces 21c of the substrate 21 and an air layer at an incident angle θ1. Similarly, the light propagating along the optical path A5 strikes the interface between another one of the side surfaces 21c of the substrate 21 and an air layer at an incident angle θ2. When each of the incident angles θ1 and θ2 is less than or equal to the critical angle of the substrate 21, at least part of the incident light is allowed to emerge from the side surfaces 21c.

In contrast thereto, the light is emitted from the optical device 3 as a comparison shown in FIG. 3 to propagate along optical paths B1 and B2. The optical paths B1 and B2 of the light emitted from the optical device 3 are similar to the optical paths A1 and A2 of the light emitted from the optical device 1. The light propagating along the optical path B2 is reflected on the upper surface of the base 33 to propagate along an optical path B3. The light propagating along the optical path B3 strikes the interface between one of the side surfaces 31c of the substrate 31 and an air layer at an incident angle θ3, which is larger than each of the incident angles θ1 and θ2 shown in FIG. 2 and also larger than the critical angle of the substrate 31. Accordingly, the incident light is totally reflected on the interface between the side surface 31c and the air layer (optical path B4). The light propagating along the optical path B4 strikes the light emitting layer 32 and is absorbed by the light emitting layer 32, so that the light cannot be extracted to the outside.

According to the optical device 1 shown in FIG. 2, the concave portion 23 like a crater is formed on the back surface 21b of the substrate 21, so that the light emitted from the light emitting layer 22 and propagating in the substrate 21 along optical paths similar to the optical path A2 can be irregularly reflected on the inner surface of the concave portion 23 and extracted to the outside along optical paths similar to the optical paths A4 and A5. Accordingly, as compared with the light propagating along optical paths similar to the optical path B2 shown in FIG. 3, the proportion of the light totally reflected on each side surface 21c to the light propagating along optical paths similar to the optical path A2 can be reduced. Accordingly, the proportion of the light repeatedly reflected in the substrate 21 and returned to the light emitting layer 22 can be reduced and the proportion of the light emerging from the substrate 21 can be increased to thereby improve the light extraction efficiency, resulting in the improvement in luminance. In the case that the proportion of the area where the concave portion 23 is formed to the total area of the back surface 21b is set to 80%, the luminance can be improved by 1 to 2% over the comparison shown in FIG. 3.

There will now be described a preferred embodiment of the optical device manufacturing method according to the present invention. The optical device manufacturing method in this preferred embodiment includes an attaching step, a division start point forming step, a concave portion forming step by a laser processing apparatus, and a dividing step by a dividing apparatus. In the attaching step, an adhesive sheet (protective tape) is attached to the front side of an optical device wafer on which a light emitting layer is formed. In the division start point forming step, a division start point where division is started is formed along each division line of the optical device wafer. In the concave portion forming step, a plurality of concave portions are formed on the back side of the optical device wafer. In the dividing step, the optical device wafer is divided along each division line where the division start point is formed, thereby obtaining a plurality of individual optical devices. These steps of the manufacturing method will now be described in more detail.

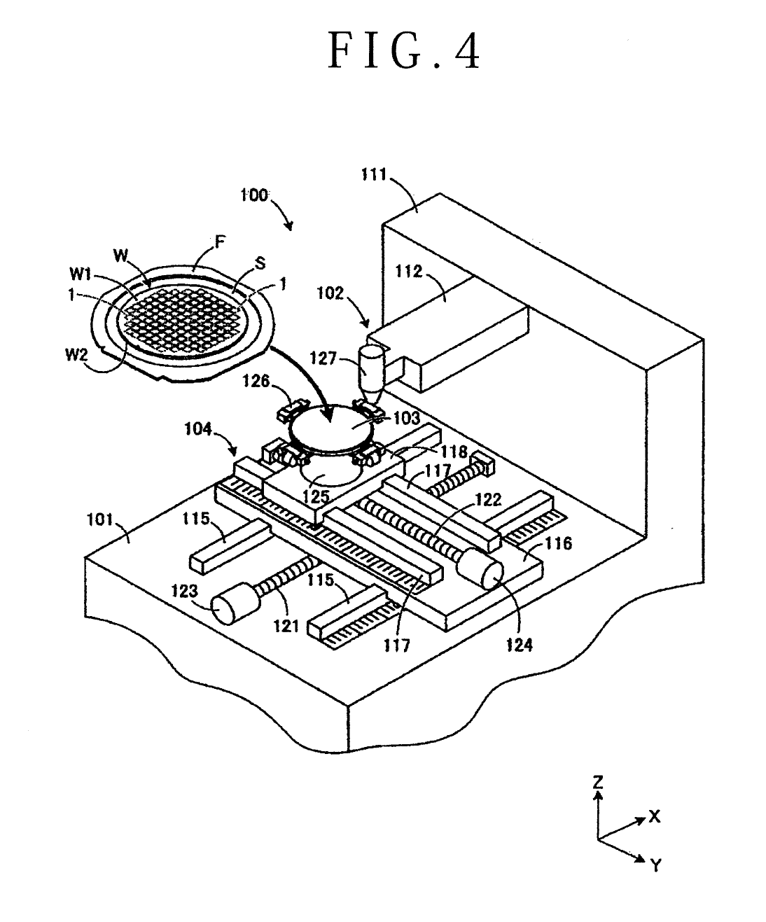

Referring to FIG. 4, there is shown a perspective view of a laser processing apparatus 100 for forming the concave portions on the back side of the optical device wafer in this preferred embodiment. The configuration of the laser processing apparatus usable in the present invention is not limited to that shown in FIG. 4. That is, any configuration capable of forming the concave portions on the back side of the optical device wafer may be adopted as the laser processing apparatus.

As shown in FIG. 4, the laser processing apparatus 100 includes a laser processing unit 102 for applying a laser beam to an optical device wafer W held on a chuck table (holding means) 103, wherein the laser processing unit 102 and the chuck table 103 are relatively moved to process the optical device wafer W.

The laser processing apparatus 100 has a boxlike base 101. There is provided on the upper surface of the base 101 a chuck table moving mechanism 104 for feeding the chuck table 103 in the X direction extending along an X axis shown in FIG. 4 and also indexing the chuck table 103 in the Y direction extending along a Y axis shown in FIG. 4. A wall portion 111 stands from the base 101 at its rear end behind the chuck table moving mechanism 104. An arm portion 112 projects from the front surface of the wall portion 111. The laser processing unit 102 is supported to the arm portion 112 so as to be opposed to the chuck table 103.

The chuck table moving mechanism 104 includes a pair of parallel guide rails 115 provided on the upper surface of the base 101 so as to extend in the X direction and a motor-driven X table 116 slidably supported to the guide rails 115. The chuck table moving mechanism 104 further includes a pair of parallel guide rails 117 provided on the upper surface of the X table 116 so as to extend in the Y direction and a motor-driven Y table 118 slidably supported to the guide rails 117.

The chuck table 103 is provided on the upper surface of the Y table 118. Nut portions (not shown) are formed on the lower surfaces of the X table 116 and the Y table 118, and ball screws 121 and 122 are threadedly engaged with these nut portions of the X table 116 and the Y table 118, respectively. Drive motors 123 and 124 are connected to the end portions of the ball screws 121 and 122, respectively. Accordingly, when the ball screws 121 and 122 are rotationally driven by the drive motors 123 and 124, respectively, the chuck table 103 is moved in the X direction and the Y direction along the guide rails 115 and 117, respectively.

The chuck table 103 is a circular member and it is rotatably provided on the upper surface of the Y table 118 through a θ table 125. A suction holding member (not shown) of a porous ceramic material is formed on the upper surface of the chuck table 103. Four clamps 126 are provided on the outer circumference of the chuck table 103, wherein each clamp 126 is supported through a pair of arms to the chuck table 103. The four clamps 126 are driven by an air actuator (not shown) to thereby fix a ring frame F supporting the optical device wafer W through an adhesive sheet S.

The laser processing unit 102 has a processing head 127 provided at the front end of the arm portion 112. An optical system is provided in the arm portion 112 and the processing head 127 to constitute the laser processing unit 102. More specifically, a laser oscillator (not shown) is provided in the arm portion 112, and the processing head 127 includes a focusing lens (not shown) for focusing a laser beam oscillated from the laser oscillator to the optical device wafer W held on the chuck table 103, thereby processing the optical device wafer W. In this case, the laser beam has an absorption wavelength to the optical device wafer W, and the focal point of the laser beam is adjusted by the optical system so that the laser beam is focused on the back side of the optical device wafer W (the upper surface as viewed in FIG. 4).

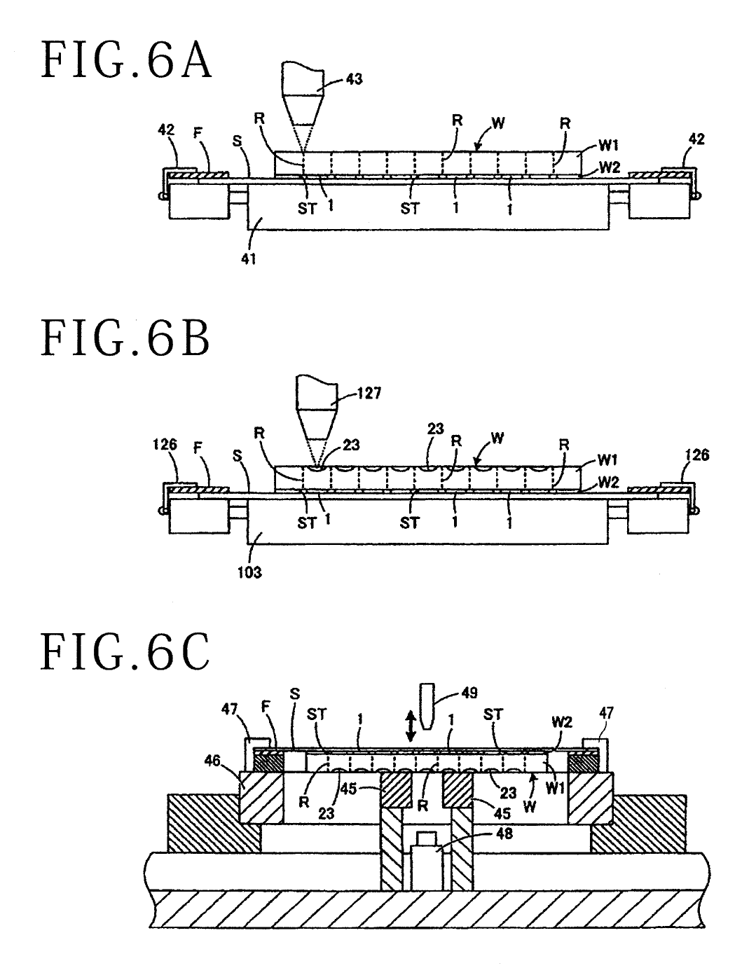

By the application of the laser beam to the optical device wafer W, ablation occurs on the back side of the optical device wafer W to partially etch the back side of the wafer W, thereby forming a plurality of concave portions 23 (see FIG. 6B) respectively corresponding to the plural optical devices 1. The ablation is a phenomenon such that when the intensity of a laser beam applied to a solid surface becomes greater than or equal to a predetermined processing threshold, the energy of the laser beam is converted to electronic, thermal, photochemical, and mechanical energy, so that neutral atoms, molecules, positive and negative ions, radicals, clusters, electrons, and light are explosively emitted to cause etching of the solid surface. In the case that the substrate W1 of the optical device wafer W to be hereinafter described is formed of sapphire, the wavelength of the laser beam in this preferred embodiment is set to 200 nm or less or 7 μm or more, at which the laser beam is totally absorbed by the sapphire.

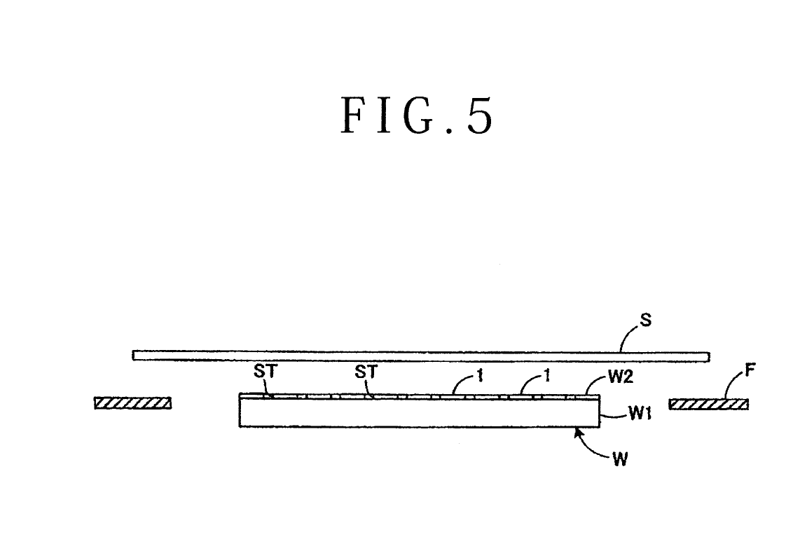

The optical device wafer W is a substantially disk-shaped member. As shown in FIG. 5, the optical device wafer W is composed of a substrate W1 and a light emitting layer W2 formed on the front side (upper surface as viewed in FIG. 5) of the substrate W1. The light emitting layer W2 of the optical device wafer W is partitioned by a plurality of crossing division lines (streets) ST to define a plurality of separate regions where a plurality of optical devices 1 are respectively formed. As shown in FIG. 4, the optical device wafer W to be held on the chuck table 103 is attached to the adhesive sheet S supported to the ring frame F in the condition where the light emitting layer W2 is oriented downward, i.e., the substrate W1 is oriented upward.

The optical device manufacturing method by processing the optical device wafer W according to this preferred embodiment will now be described with reference to FIG. 5 and FIGS. 6A to 6C. FIG. 5 and FIGS. 6A to 6C are sectional views for illustrating the steps of the optical device manufacturing method. The steps shown in FIG. 5 and FIGS. 6A to 6C are merely illustrative and the steps of the optical device manufacturing method according to the present invention are not limited to those shown in FIG. 5 and FIGS. 6A to 6C.

The attaching step shown in FIG. 5 is first performed. As shown in FIG. 5, the optical device wafer W is positioned inside the ring frame F in the condition where the light emitting layer W2 formed on the front side of the substrate W1 is oriented upward. Thereafter, the front side (upper surface) of the optical device wafer W (i.e., the light emitting layer W2) and the upper surface of the ring frame F are attached to the adhesive sheet S. Accordingly, the optical device wafer W is supported through the adhesive sheet S to the ring frame F in the condition where the substrate W1 of the wafer W is exposed.

After performing the attaching step, the division start point forming step shown in FIG. 6A is performed. As shown in FIG. 6A, the optical device wafer W supported through the adhesive sheet S to the ring frame F is held on a chuck table 41 in the condition where the adhesive sheet S is in contact with the upper surface of the chuck table 41 and the ring frame F is fixed by clamps 42. Further, the lower end (laser beam outlet) of a processing head 43 is positioned directly above a predetermined one of the division lines ST of the optical device wafer W, and a laser beam is applied from the processing head 43 toward the back side of the optical device wafer W (i.e., the back side of the substrate W1). The wavelength of the laser beam is set to a transmission wavelength to the optical device wafer W, and the focal point of the laser beam is set inside the substrate W1 of the optical device wafer W. As adjusting the focal point of the laser beam, the chuck table 41 holding the optical device wafer W is moved to thereby form a plurality of modified layers R inside the optical device wafer W along each division line ST.

In this case, the plural modified layers R along each division line ST are formed by changing the vertical position of the focal point of the laser beam along the thickness of the substrate W1. More specifically, the first modified layer R is formed by setting the vertical position of the focal point to a position near the light emitting layer W2 of the optical device wafer W and then applying the laser beam along the predetermined division line ST. The formation of the first modified layer R is repeated for all of the division lines ST. Thereafter, the focal point is shifted upward by a predetermined amount to form the second modified layer R along each division line ST. Thereafter, the laser processing is similarly performed along all of the division lines ST until the total thickness of the plural modified layers R along each division line ST becomes a predetermined thickness. Thusly, a division start point where division is started is formed by the plural modified layers R along each division line ST. Each modified layer R is a region different from its ambient region in density, refractive index, mechanical strength, or any other physical properties in the optical device wafer W irradiated with the laser beam, causing a reduction in strength as compared with the ambient region. Examples of each modified layer R include a melted and rehardened region, cracked region, breakdown region, and refractive index changed region. These regions may be mixed.

After performing the division start point forming step, the concave portion forming step shown in FIG. 6B is performed. As shown in FIG. 6B, the optical device wafer W supported through the adhesive sheet S to the ring frame F is held on the chuck table 103 in the condition where the adhesive sheet S is in contact with the upper surface of the chuck table 103 and the ring frame F is fixed by the clamps 126. Further, the lower end (laser beam outlet) of the processing head 127 is positioned directly above the center of a predetermined one of the plural devices 1 of the optical device wafer W, and a laser beam is applied from the processing head 127 toward the back side of the optical device wafer W (i.e., the back side of the substrate W1). The wavelength of the laser beam is set to an absorption wavelength to the optical device wafer W, and the focal point of the laser beam is set on the back side of the optical device wafer W. After applying the laser beam to the back side of the optical device wafer W for a predetermined period of time to thereby perform the ablation, the chuck table 103 holding the optical device wafer W is moved in the X direction and the Y direction where the plural optical devices 1 are arranged, and the laser processing is then similarly performed at the positions respectively corresponding to all of the optical devices 1. Thus, the concave portion 23 having a predetermined depth is formed on the back side of the optical device wafer W at the position where each optical device 1 is formed. After performing this ablation, the inner surface of each concave portion 23 is treated with etching (e.g., wet etching), thereby removing debris on the inner surface of each concave portion 23.

After performing the concave portion forming step, the dividing step shown in FIG. 6C is performed. In this preferred embodiment, a breaking operation is performed as the dividing step. As shown in FIG. 6C, the substrate W1 of the optical device wafer W is placed on a pair of parallel support beds 45 constituting a breaking apparatus (not shown), and the ring frame F supporting the optical device wafer W through the adhesive sheet S is placed on an annular table 46. The ring frame F placed on the annular table 46 is fixed by four clamps 47 provided on the annular table 46. The pair of parallel support beds 45 extend in one direction (perpendicular to the sheet plane of FIG. 6C), and imaging means 48 is located between the support beds 45 on the lower side thereof. The imaging means 48 functions to image the back side (lower surface as viewed in FIG. 6C) of the optical device wafer W, i.e., the back side of the substrate W1 from between the support beds 45.

A pressure blade 49 for pressing the optical device wafer W from the upper side thereof is provided above the support beds 45 at a horizontal position therebetween. That is, an external force is applied from the pressure blade 49 to the optical device wafer W held on the support beds 45. The pressure blade 49 extends in one direction (perpendicular to the sheet plane of FIG. 6C), and it is vertically movable by a pressure applying mechanism (not shown). When the back side of the optical device wafer W is imaged by the imaging means 48, a predetermined one of the division lines ST is positioned between the support beds 45 and directly below the pressure blade 49 according to an image obtained by the imaging means 48. Thereafter, the pressure blade 49 is lowered to abut against the optical device wafer W through the adhesive sheet S, thereby applying an external force to the optical device wafer W to divide the wafer W along the predetermined division line ST where the plural modified layers R as a division start point are formed. This dividing step is similarly performed along all of the division lines ST to thereby divide the optical device wafer W into the individual optical devices 1.

An example of the laser processing conditions in the concave portion forming step is shown below.

### Example

Light source: CO₂ laser

Wavelength: 9.4 μm (infrared radiation)

Power: 5 W

Repetition frequency: 1 kHz

Pulse width: 20 μsec

Focused spot diameter: 200 μm

Work feed speed: 600 mm/s

By using the optical device 1 obtained in Example, the total intensity (power) of light radiated was measured (total radiant flux measurement). As compared with the conventional optical device having the flat back surface as shown in FIG. 3, the luminance of the optical device 1 according to this preferred embodiment was improved by 1 to 2%.

According to the optical device manufacturing method in this preferred embodiment, the concave portions 23 can be quickly formed by ablation. Further, the concave portions 23 can be successively formed on the back surfaces of the plural optical devices 1 of the optical device wafer W. As a result, complication of the concave portion forming step and elongation of the time of this step can be suppressed to thereby effect efficient manufacture of the optical devices 1. Furthermore, since the inner surface of each concave portion 23 is treated with etching to thereby remove debris after performing the ablation, the luminance of each optical device 1 can be further improved.

The present invention is not limited to the above preferred embodiment, but various modifications may be made. The size, shape, etc. of the parts in the above preferred embodiment shown in the attached drawings are merely illustrative and they may be suitably changed within the scope where the effect of the present invention can be exhibited. Further, the above preferred embodiment may be suitably modified without departing from the scope of the object of the present invention. For example, while the concave portion forming step is performed before performing the dividing step in the above preferred embodiment, the concave portion forming step may be performed after performing the dividing step or may be performed between the attaching step and the division start point forming step.

Further, while the optical device wafer W is divided by combining the division start point forming step and the breaking operation in the above preferred embodiment, the dividing step in the present invention is not limited to this configuration. That is, the dividing step in the present invention may be performed by using any apparatus capable of dividing the optical device wafer W along the division lines ST to obtain the individual optical devices 1. For example, the optical device wafer W may be divided by combining the division start point forming step and an expanding operation of expanding the adhesive sheet S to thereby apply an external force to the modified layers R formed along the division lines ST.

Further, a division groove may be formed along each division line ST on the optical device wafer W by ablation in the division start point forming step. As a modification, this division groove may be formed as a half-cut groove by using a cutting blade. In any case, the breaking operation as the dividing step may be replaced by the expanding operation. In the case of performing the concave portion forming step after performing the dividing step, a DBG (Dicing Before Grinding) operation may be performed to grind the back side of the optical device wafer W after forming a half-cut groove along each division line ST on the front side of the optical device wafer W, thereby dividing the optical device wafer W into the individual optical devices 1. As a modification, a full-cut groove may be formed along each division line ST by using a cutting blade to thereby divide the optical device wafer W.

Further, the steps of the optical device manufacturing method in the above preferred embodiment may be performed by using separate apparatuses or by using the same apparatus.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. An optical device comprising:
a substrate; and
a light emitting layer formed on a front surface of the substrate,
wherein a back surface of the substrate is formed with a concave portion.

2. A manufacturing method for optical devices each including a substrate and a light emitting layer formed on a front surface of the substrate, wherein a back surface of the substrate is formed with a concave portion, the manufacturing method comprising:
an attaching step of attaching a protective tape to a front side of an optical device wafer having a light emitting layer on the front side, the light emitting layer of the optical device wafer being partitioned by a plurality of crossing division lines to define a plurality of separate regions where the optical devices are respectively formed;
a division start point forming step of forming a division start point where division is started along each division line of the optical device wafer after performing the attaching step;
a dividing step of applying an external force to the optical device wafer along each division line after performing the division start point forming step, thereby dividing the optical device wafer along each division line to obtain the individual optical devices; and
a concave portion forming step of applying a laser beam having an absorption wavelength to the optical device wafer before or after performing the dividing step, thereby forming a plurality of concave portions on a back side of the optical device wafer at positions respectively corresponding to the optical devices.

3. The manufacturing method according to claim 2, wherein the concave portion forming step includes an etching step of etching an inner surface of the concave portion formed on the back side of the optical device wafer.
